(19) United States
(12) Patent Application Publication
(10) Pub. No.: US 2014/0211431 A1
(43) Pub. Date: Jul. 31, 2014

(54) ORGANIC LIGHT EMITTING DIODE DISPLAY DEVICE

(71) Applicant: Samsung Display Co., Ltd., Yongin-City (JP)

(72) Inventors: Min-Ho Um, Yongin-City (KR); Jong-Nam Lee, Yongin-City (KR); Ik-Jun Hong, Yongin-City (KR)

(21) Appl. No.: 14/161,971

(22) Filed: Jan. 23, 2014

(30) Foreign Application Priority Data
Jan. 25, 2013 (KR) 10-2013-0008746

(51) Int. Cl. H05K 7/02

(52) U.S. Cl. CPC H05K 7/02
USPC 361/757; 361/752

(57) ABSTRACT

An organic light emitting diode (OLED) display device includes: a display panel including a display area and a non-display area provided in an external side of the display area; a set frame disposed on a rear surface of the display panel and supporting the display panel; a side frame surrounding a side surface of the display panel and covering the non-display area; and a cover window covering the display area disposed in an inner space surrounded by the side frame.

### RELATED APPLICATION

This application claims priority to and the benefit of Korean Patent Application No. 10-2013-0008746 filed in the Korean Intellectual Property Office on Jan. 25, 2013, the entire contents of which are incorporated herein by reference.

### BACKGROUND

1. Field

The present invention relates to an organic light emitting diode (OLED) display device. More particularly, the present invention relates to an assembly structure of a cover window and a set frame that protect a display panel by surrounding the same.

2. Description of the Related Art

An organic light emitting diode (OLED) display device includes a display panel displaying an image, a cover window, and a set frame. The cover window and the set frame protect the display panel by surrounding the same. The set frame surrounds a rear surface and a side surface of the display panel by forming a space in which the display panel is seated, and the cover window is fixed to the set frame from an external side of a display surface of the display panel to protect the display panel from external impact, scratch, and the like.

In general, the cover window is made of high-lustrous glass material, and is formed larger than the display panel in size. In addition, an edge of the cover window protruding to the external side of the display panel is fixed to the set frame.

However, in the above-described structure, a drop impact is directly transferred to the cover window so that the display panel may be damaged, and a dead space formed along the edge of the display panel is relatively wide. Here, no substantial display occurs in the dead space. In addition, the front surface of the OLED display is entirely covered with high-lustrous glass so that the design may be simple.

The above information disclosed in this Background section is only for enhancement of understanding of the background of the invention and therefore it may contain information that does not form the prior art that is already known in this country to a person of ordinary skill in the art.

### SUMMARY

The present invention has been made in an effort to provide an organic light emitting diode (OLED) display device that can suppress damage to a cover window by reducing impact applied to the cover window from drop, reduce the width of a dead space, and vary design factors with combination of a lustrous material and a matt material.

An OLED display device according to an exemplary embodiment of the present invention includes: a display panel including a display area and a non-display area provided in an external side of the display area; a set frame disposed on a rear surface of the display panel and supporting the display panel; a side frame surrounding a side surface of the display panel and covering the non-display area; and a cover window covering the display area disposed in an inner space surrounded by the side frame.

The set frame may form a flat surface facing the display panel and formed larger than the display panel in width, and the display panel may be fixed to the flat surface of the set frame by an adhesive member.

The side frame may include a vertical portion surrounding the side surface of the display panel and a horizontal portion covering the non-display area of the display panel. A size of the cover window may be the same as a size of the display area. The cover window may be disposed in parallel with the horizontal portion in an inner space surrounded by the horizontal portion.

The side frame may be made of a metal and the cover window is made of glass or plastic. The side frame may be made of aluminum or an aluminum alloy, and may have a matt-finished surface.

A resin layer may be formed between the display panel and the cover window, and may formed between the display panel and the horizontal portion so that the display panel, the cover window, and the side frame may be integrally bonded.

The side frame may be formed larger than the horizontal portion in thickness, and the external surface of the cover window and the external surface of the horizontal portion may maintain the same level. The thickness of a portion of the resin layer contacting the cover window may be smaller than the thickness of a portion of the resin layer contacting the horizontal portion.

The non-display area may include a pad area, and the horizontal portion of the side frame may cover the pad area.

When the OLED display device is dropped, the drop impact is transferred to the cover window through the side frame so that damage to the cover window and the display panel can be suppressed by reducing the impact transferred to the cover window. In addition, a ultra slim bezel can be realized by reducing the width of the dead space formed in the external side of the display area, and the design factors can be varied with combination of the cover window made of a lustrous material and the side frame made of a matt material.

### BRIEF DESCRIPTION OF THE DRAWINGS

FIG. 1 is a front view of an OLED display device according to an exemplary embodiment of the present invention.

FIG. 2 is a cross-sectional view of the OLED display device of FIG. 1, taken along the line A-A.

FIG. 3 is a perspective view of a display panel of FIG. 2.

FIG. 4 is a cross-sectional view of the display panel of FIG. 3, taken along the line B-B.

### DETAILED DESCRIPTION

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

Throughout the specification, unless explicitly described to the contrary, the word “comprise” and variations such as “comprises” or “comprising”, will be understood to imply the inclusion of stated elements but not the exclusion of any other elements. In addition, in the specification, it will be understood that when an element such as a layer, film, region, or substrate is referred to as being “on” another element, it can be directly on the other element or intervening elements may also be present. Furthermore, a term ‘over’ or ‘on’ means that a specific part is placed over or under a target part, but does not necessarily mean that the specific part is placed over the target part on the basis of the gravity direction.

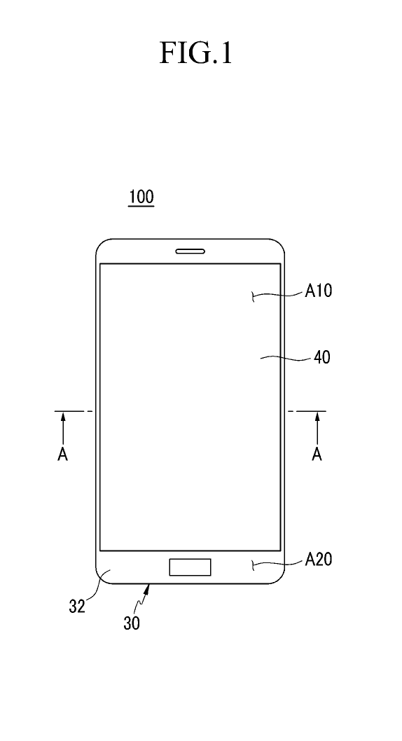

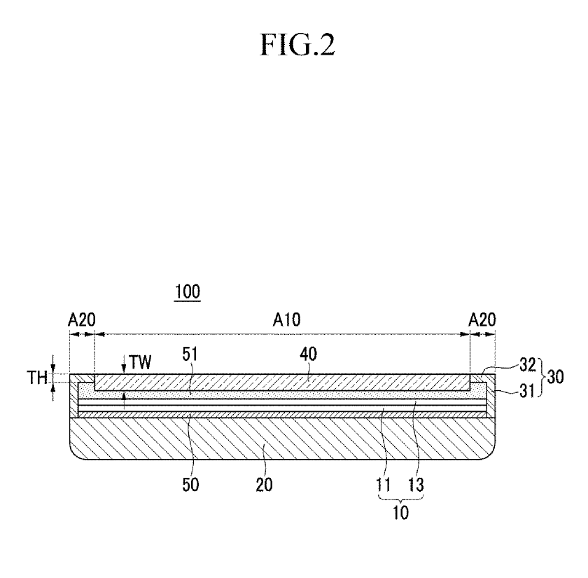

FIG. 1 is a front view of an organic light emitting diode (OLED) display device according to an exemplary embodiment of the present invention and FIG. 2 is a cross-sectional view of the OLED display device of FIG. 1, taken along the line A-A.

Referring to FIG. 1 and FIG. 2, an OLED display device 100 includes a display panel 10, a set frame 20 and a side frame 30 protecting the display panel 10 by surrounding the same, and a cover window 40.

The display panel 10 forms a display area A10 in a display side and a non-display area A20 surrounding the display area A10. The set frame 20 is disposed in an external rear surface of the display panel 10, the side frame 30 surrounds a side surface of the display panel 10 and covers the non-display area A20 of the display panel 10, and the cover window 40 is disposed to cover the display area A10 that is disposed in an inner space surrounded by the side frame 30.

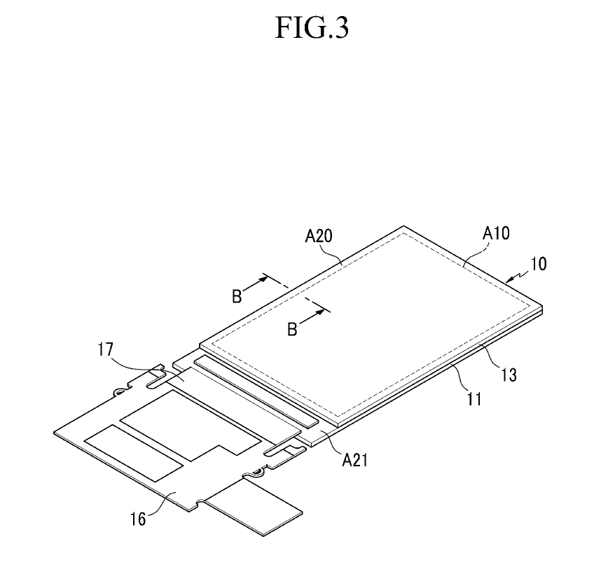

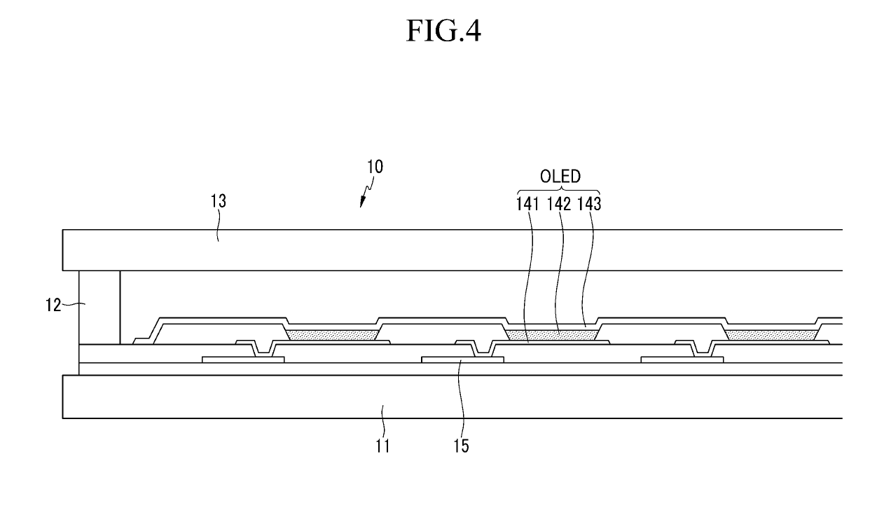

FIG. 3 is a perspective view of the display panel shown in FIG. 2, and FIG. 4 is a cross-sectional view of the display panel of FIG. 3, taken along the line B-B.

Referring to FIG. 3 and FIG. 4, the display panel 10 includes a substrate 11, a plurality of organic light emitting diodes OLED formed on the substrate 11, and an encapsulation substrate 13 fixed to the substrate 11 by a sealant 12 to seal the plurality of organic light emitting diodes OLED. In addition, a touch screen panel (not shown) that senses touching of a user may be provided in an external side of the display side of the display panel 10.

The substrate 11 may be made of glass, polymer film, or metal, and a plurality of pixel circuits and a plurality of organic light emitting diode OLEDs are disposed in the display area A10. The pixel circuit and the organic light emitting diode OLED are provided in each pixel. The pixel circuit includes at least two thin film transistor (i.e., a switching thin film transistor and a driving thin film transistor) and at least one capacitor. The organic light emitting diode OLED includes a pixel electrode 141, an organic emission layer 142, and a common electrode 143.

FIG. 4 schematically illustrates only the driving thin film transistor 15 as one layer among the pixel circuits. The pixel electrode 141 is individually provided in each pixel and electrically connected with the driving thin film transistor 15. On the contrary, the common electrode 143 is formed through the substrate 11 and connected with a power source ELVSS.

One of the pixel electrode 141 and the common electrode 143 is an anode and the other is a cathode. In addition, one of the pixel electrode 141 and the common electrode 143 may be formed as a metal layer and the other may be formed as a transparent conductive layer. Electrons injected from the anode and holes injected from the cathode are coupled with each other on the organic emission layer 142 to form excitons and the excitons emit light while emitting energy. Light from the organic emission layer 142 is reflected by the metal layer and emitted to the outside through the transparent conductive layer.

When the pixel electrode 141 is formed as a metal layer and the common electrode 143 is formed as a transparent conductive layer, an external surface of the encapsulation substrate 13 becomes the display side of the display panel 10. On the contrary, when the pixel electrode 141 is formed as a transparent conductive layer and the common electrode 143 is formed as a metal layer, an external surface of the substrate 11 becomes the display side of the display panel 10. FIG. 2 to FIG. 4 exemplarily illustrate that the external surface of the encapsulation substrate 13 becomes the display side.

A plurality of signal lines and the sealant 12 are provided in the non-display area A20 that surrounds the display area A10. In addition, the substrate 11 is formed larger than the encapsulation substrate 13 and thus forms a pad area A21 that does not overlap the encapsulation substrate 13. The pad area A21 is also included in the non-display area A20.

A plurality of pad electrodes (not shown) are formed in the pad area A21, and a connection film (i.e., a chip on film COF) 17 connected with a printed circuit board (i.e., a flexible printed circuit FPC) 16 is fixed to the pad area A21 while being connected with the plurality of pad electrodes. The circuit film 17 is bent toward a rear side of the display panel 10 such that the printed circuit board 16 is disposed in the rear side of the display panel 10.

The encapsulation substrate 13 may be formed of glass or a polymer film, and is fixed to the substrate 11 by the sealant 12. The encapsulation substrate 13 seals the organic light emitting diode OLED from an external environment that contains moisture and oxygen to suppress deterioration of the organic light emitting diode OLED due to moisture and oxygen.

Meanwhile, the sealant 12 and the encapsulation substrate 13 may be omitted and a thin film encapsulation layer (not shown) may be directly formed on the plurality of organic light emitting diodes. The thin film encapsulation layer may have a structure in which a plurality of organic layers and a plurality of inorganic layers are alternately layered. FIG. 3 and FIG. 4 exemplarily illustrate that the display panel 10 is provided with the sealant 12 and the encapsulation substrate 13.

Referring back to FIG. 1 and FIG. 2, the set frame 20 does not form a concave space for receiving the display panel 10 but forms a flat surface facing the display panel 10. In this case, the set frame 20 is formed wider than the display panel 10 in width, and is fixed to an inner center (or middle portion) of the set frame 20 by an adhesive member 50 such as a double-sided adhesive tape. A buffering member (not shown) such as a foaming sponge may be additionally provided between the display panel 10 and the set frame 20.

The side frame 30 covers a side surface and the non-display area A20 of the display panel 10. In further detail, the side frame 30 is formed of a vertical portion 31 surrounding the side surface of the display panel 10 and a horizontal portion 32 surrounding or covering the non-display area A20 of the display panel 10, and an opening (or space) is formed to expose the display area A10 in a center portion of the horizontal portion 32.

The side frame 30 may be made of a metal, for example, light and strong aluminum or an aluminum alloy, and may have a matt-finished surface. The side frame 30 may be formed to cover the entire non-display area A20 including the pad area A21 (referring to FIG. 3) disposed in the external side of the display side of the display panel 10.

The cover window 40 is disposed in parallel with the horizontal portion 32 of the side frame 30 in an external side of the display area A10 of the display panel 10. In the other words, as shown in FIG. 2, the horizontal portion of the side frame 30 is disposed on the same level as the cover window 40. The cover window 40 is disposed in the opening of the side frame 30. Unlike a conventional cover window that is formed larger than the display panel 10 in size, the cover window 40 is smaller than the display panel 10 in size, or may be the same as the display area A10 in size.

A resin layer 51 cured by ultraviolet (UV) ray or heat is formed between the display panel 10 and the cover window 40 to integrally bond the display panel 10 to the cover window 40. The resin layer 51 is not only formed between the display panel 10 and the cover window 40 but also formed between the display panel 10 and the side frame 30 to integrally bond the display panel 10 to the side frame 30.

The cover window 40 is made of a lustrous glass or plastic material, and the thickness TW of the cover window 40 may be larger than the thickness TH of the horizontal portion 32 of the side frame 30. An external surface of the cover window 40 may maintain the same height with an external surface of the horizontal portion 32, and for this, the thickness of the resin layer 51 that contacts the cover window 40 may be smaller than the thickness of the resin layer 51 contacting the horizontal portion 32. In the specification, the terms of size and width refer to the dimension perpendicular to the thickness.

Since the side frame 30 is bonded to the display panel 10 by the resin layer 51 and the display panel 10 is fixed to the set frame 20 by the adhesive member 50, an adhesive member between the set frame 20 and the side frame 30 may be omitted or provided if necessary. FIG. 2 exemplarily illustrates that the adhesive member between the set frame 20 and the side frame 30 is omitted.

Unlike a conventional structure in which a set frame forms a concave space for receiving a display panel and a cover window formed larger than the display panel is fixed to the set frame, in the above-described OLED display device 100, a side surface of the display panel and the side frame 30 covering the non-display area A20 are disposed along the edge of the display panel 10 and the cover window 40 is formed with the same size of the display area A10 of the display panel 10.

Accordingly, when the OLED display device 100 is dropped, impact due to the drop is not transferred directly to the cover window 40 but is indirectly transferred to the cover window 40 through the side frame 30. In this case, since the side frame 30 is formed of an impact-resistant metal, the degree of impact transferred to the cover window 40 is decreased. Accordingly, damage to the cover window 40 and the display panel 10 due to the drop impact can be suppressed.

In addition, since only the vertical portion 31 of the side frame 30 is disposed in the outer side of the side surface of the display panel 10, the width of a dead space in the external side of the display area A10 can be effectively reduced.

In addition, since the lustrous cover window 40 is disposed only in the display area A10 and the matt side frame 30 is disposed only in the non-display area A20, a design can be varied by combination of a lustrous material and a matt material. Thus, compared to a simple design of a conventional structure in which only the cover window 40 is disposed in a front side of the display panel 10, a more sophisticated design can be realized.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An organic light emitting diode (OLED) display device, comprising:
a display panel including a display area and a non-display area provided in an external side of the display area;
a set frame disposed on a rear surface of the display panel and supporting the display panel;
a side frame surrounding a side surface of the display panel and covering the non-display area; and
a cover window covering the display area disposed in an inner space surrounded by the side frame.

2. The OLED display device of claim 1, wherein the set frame forms a flat surface facing the display panel and formed larger than the display panel in width, and the display panel is fixed to the flat surface of the set frame by an adhesive member.

3. The OLED display device of claim 2, wherein the side frame comprises a vertical portion surrounding the side surface of the display panel and a horizontal portion covering the non-display area of the display panel, a size of the cover window being the same as a size of the display area, the cover window being disposed in parallel with the horizontal portion in an inner space surrounded by the horizontal portion.

4. The OLED display device of claim 3, wherein the side frame is made of a metal, and the cover window is made of a material selected from the group consisting of glass, plastic and combinations thereof.

5. The OLED display device of claim 4, wherein the side frame is made of a material selected from the group consisting of aluminum, an aluminum alloy and combinations thereof, and has a matt-finished surface.

6. The OLED display device of claim 3, further comprising a resin layer formed between the display panel and the cover window, the resin layer formed between the display panel and the horizontal portion so that the display panel, the cover window, and the side frame are integrally bonded.

7. The OLED display device of claim 6, wherein the side frame is formed larger than the horizontal portion in thickness, and the external surface of the cover window and the external surface of the horizontal portion maintain the same level.

8. The OLED display device of claim 7, wherein a thickness of a portion of the resin layer that contacts the cover window is smaller than a thickness of a portion of the resin layer that contacts the horizontal portion.

9. The OLED display device of claim 3, wherein the non-display area comprises a pad area, and the horizontal portion of the side frame covers the pad area.
